(19) United States
(12) Patent Application Publication
(10) Pub. No.: US 2009/0290307 A1
(43) Pub. Date: Nov. 26, 2009

(54) CENTRIFUGAL BLOWER AND ELECTRONIC DEVICE INCORPORATING THE SAME

(75) Inventors: CHING-BAI HWANG, Tu-Cheng (TW); ZHI-HUI ZHAO, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: FURUI PRECISE COMPONENT (KUNSHAN) CO., LTD., KunShan City (CN); FOXCONN TECHNOLOGY CO., LTD., Tu-Cheng (TW)

(21) Appl. No.: 12/331,392

(22) Filed: Dec. 9, 2008

(30) Foreign Application Priority Data
May 23, 2008 (CN) 200810067415.5

(51) Int. Cl. H05K 7/20; F04D 25/08

(52) U.S. Cl. 361/695; 165/121; 417/423.1

(57) ABSTRACT

A centrifugal blower includes a housing, a stator and a rotor. The housing includes a base plate defining an air inlet therein and a sidewall extending upwardly from a periphery of the base plate. The sidewall defines an air outlet therein. The base plate includes a supporting portion disposed in the air inlet. The supporting portion protrudes downwardly beyond a bottom surface of the base plate and connects with the base plate via a plurality of ribs extending radially outwardly and upwardly from a periphery of the supporting portion toward the base plate. The stator is mounted on the supporting portion and the rotor is rotatably disposed around the stator.

### BACKGROUND

1. Field of the Disclosure

The disclosure generally relates to centrifugal blowers, and particularly to a centrifugal blower having an improved housing and an electronic device incorporating the centrifugal blower.

2. Description of Related Art

It is well-known that heat is generated by electronic components such as central processing units (CPUs) of computers. If the generated heat is not rapidly and efficiently removed, the electronic component may overheat and the performance thereof may be significantly degraded.

Conventionally, a centrifugal blower is mounted in an enclosure of an electronic device such as a notebook compute to remove heat generated by the electronic components in the electronic device. The centrifugal blower includes a housing, a stator and a rotor having a hub and a plurality of blades extending radially from the hub. The housing includes a top plate, a bottom plate parallel to the top plate and a sidewall interconnecting the top plate and the bottom plate. A first air inlet and a second air inlet are defined in central portions of the top and bottom plates of the housing respectively, and an air outlet is defined in the sidewall of the housing and is oriented perpendicularly to the air inlets. In use, the blades of the centrifugal fan rotate to produce airflow flowing towards the electronic component via the air outlet, thus cooling the electronic component continuously.

Generally, when the centrifugal blower is mounted in the enclosure of the electronic device, a distance about 0.5 millimeter to 3 millimeter is formed between a top cover of the enclosure and the top plate of the centrifugal blower to introduce air into the centrifugal blower via the first air inlet, and a distance about 0.5 millimeter to 3 millimeter is also formed between a bottom cover of the enclosure and the bottom plate of the centrifugal blower to introduce air into the centrifugal blower via the second air inlet. Therefore, the electronic device incorporating the above-mentioned centrifugal blower is thick, which can not meet the tendency of miniaturizing the electronic device.

What is needed, therefore, is a centrifugal blower, which overcomes the described limitations.

### BRIEF DESCRIPTION OF THE DRAWINGS

FIG. 1 is an exploded, isometric view of a centrifugal blower in accordance with an exemplary embodiment.

FIG. 2 is an assembled view of the centrifugal blower of FIG. 1.

FIG. 3 is similar to FIG. 2, but viewed from another aspect.

FIG. 4 is a cross-sectional view of the centrifugal fan of FIG. 1 mounted in an electronic device.

FIG. 5 is a cross-sectional view of the centrifugal fan of FIG. 1 mounted in an inverted state in an electronic device.

### DETAILED DESCRIPTION

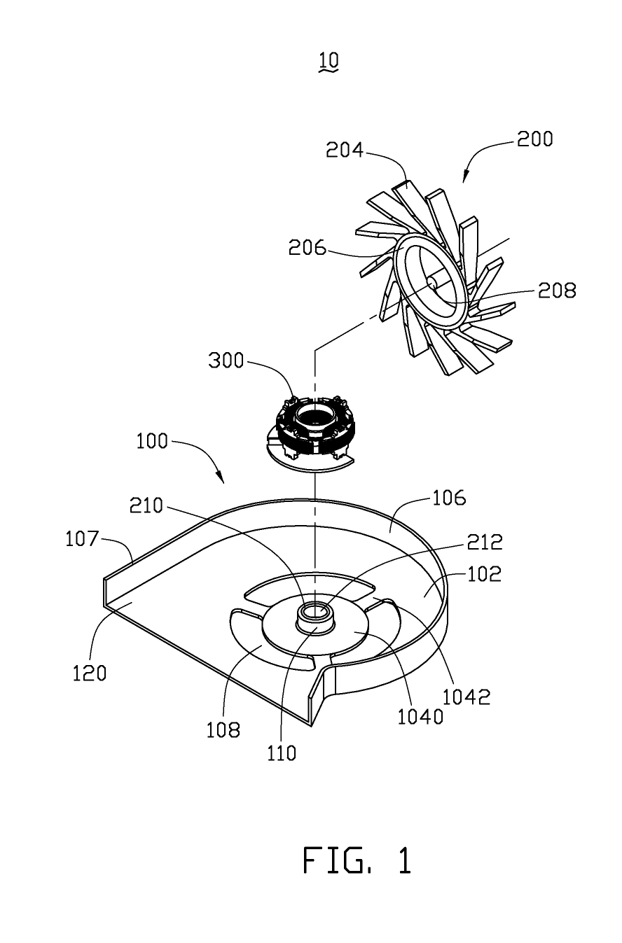

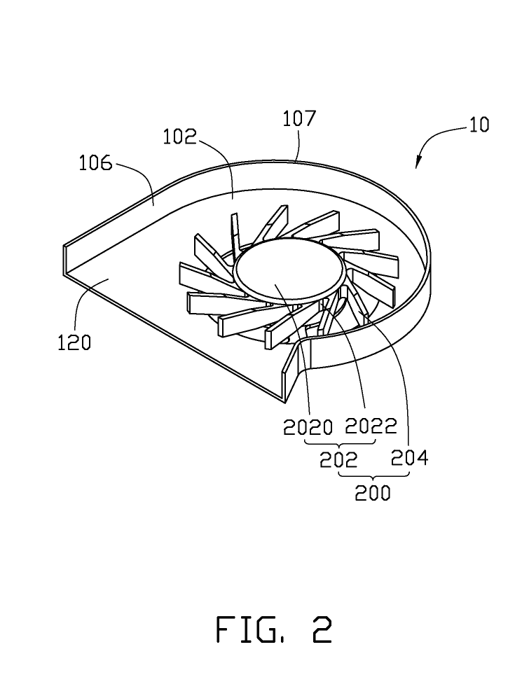

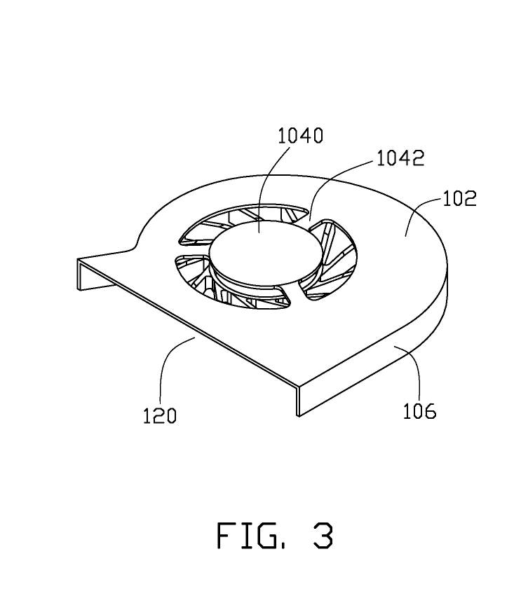

Referring to FIGS. 1-3, a centrifugal blower 10 includes a housing 100, a stator 300 mounted in the housing 100 and a rotor 200 rotatably disposed around the stator 300. When the centrifugal blower 10 is in operation, the stator 300 is electrified to generate magnetic field which drives the rotor 200 to rotate.

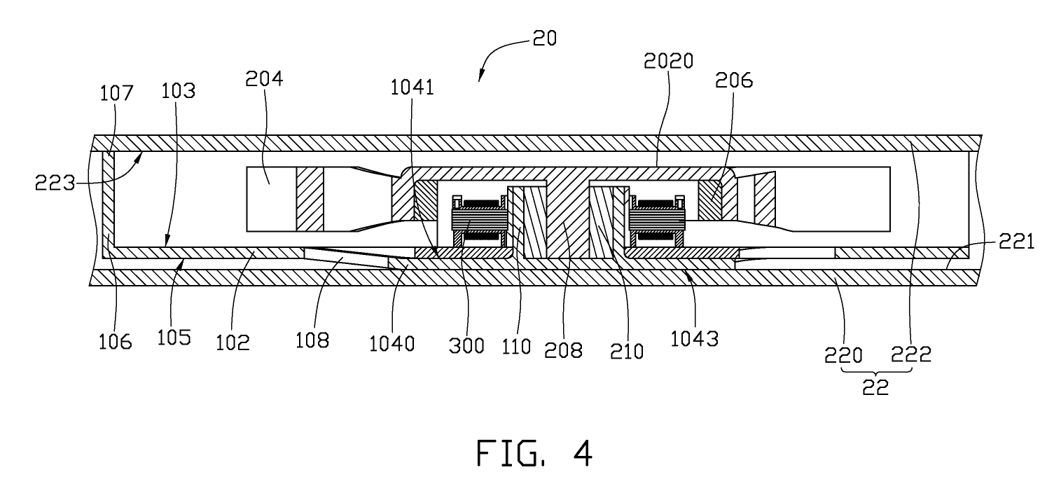

The housing 100 includes a base plate 102 and a sidewall 106 perpendicularly and upwardly extending from a periphery of the base plate 102. The sidewall 106 defines a linear-shaped opening therein functioning as an air outlet 120 of the centrifugal blower 10. Airflow produced by the centrifugal blower 10 flows out of the housing 100 via the air outlet 120. The base plate 102 is planar and defines an air inlet 108 therein. The air inlet 108 is circular. The exterior air enters into the housing 100 of centrifugal blower 10 via the air inlet 108. The base plate 102 includes a rounded and planar supporting portion 1040 disposed in the air inlet 108 of the centrifugal blower 10 for supporting the rotor 200 thereon. As shown in FIG. 4, the supporting portion 1040 is parallel to and lower than the base plate 102, thereby forming an indent at a center of a top surface 103 (i.e., inner surface) of the base plate 102 and a protrusion at a center of a bottom surface 105 (i.e., outer surface) of the base plate 102. In other words, the supporting portion 1040 protrudes downwardly beyond the bottom surface 105 of the base plate 102. A top surface 1041 of the supporting portion 1040 is substantially coplanar with the bottom surface 105 of the base plate 102 and a bottom surface 1043 of the supporting portion 1040 is lower than the bottom surface 105 of the base plate 102. Three ribs 1042 extend slantwise upwardly from a periphery of the supporting portion 1040 to the base plate 102 so as to connect the supporting portion 1040 with the base plate 102. The air inlet 108 is divided into three sector-shaped apertures (not labeled) by the ribs 1042 and the supporting portion 1040. A central tube 110 extends upwardly from a center of the supporting portion 1040. A central hole 212 is defined in the central tube 110 receiving a bearing 210 therein (FIG. 4).

The rotor 200 includes a hub 202, a plurality of blades 204 and a permanent magnet 206. The hub 202 has a circular top wall 2020 and a circumferential periphery wall 2022 depending from the top wall 2020. The blades 204 extend radially and evenly from the periphery wall 2022 of the hub 202. The permanent magnet 206 is attached to an inner surface of the periphery wall 2022 of the hub 202. A shaft 208 extends perpendicularly and downwardly from an inner side of the top wall 2020 of the hub 202. As shown in FIG. 4, when the centrifugal blower 10 is assembled, the stator 300 is mounted on an outer periphery of the central tube 110. The shaft 208 of the rotor 200 is inserted in the bearing 210 received in the central tube 110. The permanent magnet 206 surrounds and confronts the stator 300.

Referring to FIG. 4, a cross-sectional view of an electronic device 20 incorporating the centrifugal blower 10 therein is shown. The electronic device 20 is a portable electronic product such as a notebook computer, a portable DVD player, etc. The electronic device 20 includes an enclosure 22 having a bottom cover 220 and an opposing top cover 222 parallel to the bottom cover 220. The centrifugal blower 10 is mounted between the top cover 222 and the bottom cover 220. The supporting portion 1040 of the centrifugal blower 10 contacts with a top surface 221 of the bottom cover 220 and a free end 107 of the sidewall 106 of the centrifugal blower 10 abuts a bottom surface 223 of the top cover 222. Thus, the top cover 222 of the enclosure 22 functions as a cover of the centrifugal blower 10.

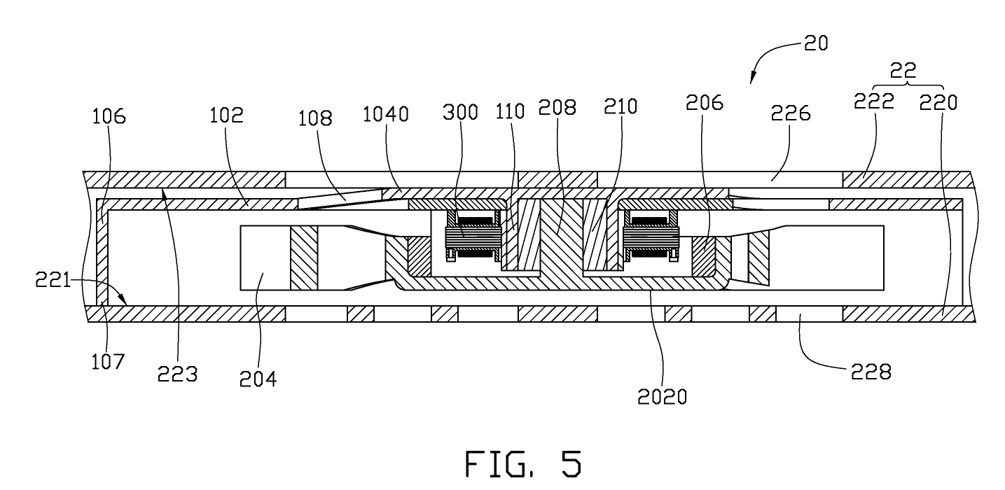

Alternatively, as shown in FIG. 5, the centrifugal blower 10 can be mounted inversely in the enclosure 22 of the electronic device 20. In this case, the supporting portion 1040 contacts with the bottom surface 223 of the top cover 222 and the free end 107 of the sidewall 106 of the centrifugal blower 10 abuts the top surface 221 of the bottom cover 220. The top cover 222 and the bottom cover 220 further define a plurality of first through holes 226 and a plurality of second through holes 228 at regions corresponding to the rotor 200 of the centrifugal blower 10. The air outside the enclosure 22 is introduced into the centrifugal blower 10 via the through holes 226 of the top cover 222 and through holes 228 of the bottom cover 220.

In the present embodiment, the supporting portion 1040 protrudes downwardly beyond the bottom surface 105 of the base plate 102. When the centrifugal blower 10 is mounted in the enclosure 22 of the electronic device 20 and the supporting portion 1040 of the centrifugal blower 10 abuts the top cover 222 (FIG. 5) or the bottom cover 220 (FIG. 4) of the electronic device 20, the air inlet 108 defined in the base plate 102 will not be blocked. Furthermore, because the free end 107 of the sidewall 106 abuts the enclosure 22, it is not necessary to form a top plate for the housing 100 of the centrifugal blower 10. Thus, a room defined by the housing 100 for receiving the stator 300, the bearing 210 and the rotor 200 can be enlarged. Thus, heights of the bearing 210 and the shaft 208 of the rotor 200 can be correspondingly increased, which makes the centrifugal blower 10 run more stably. Heights of the stator 300 and the permanent magnet 206 can also be correspondingly increased, which increases the intensity of the magnetic field generated by the stator 300 acting on the permanent magnet 206 of the rotor 200. Thus, the rotation speed of the rotor 200 can be increased.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A centrifugal blower comprising:
a housing comprising a base plate defining an air inlet therein and a sidewall extending substantially perpendicularly and upwardly from a periphery of the base plate, the sidewall defining an air outlet therein, a supporting portion disposed in the air inlet, the supporting portion protruding downwardly beyond a bottom surface of the base plate;
a stator mounted on the supporting portion; and
a rotor rotatably disposed around the stator.

2. The centrifugal blower as described in claim 1, wherein a plurality of ribs extend outwardly from a periphery of the supporting portion to connect with the base plate, the air inlet being divided into a plurality of sector-shaped apertures by the ribs.

3. The centrifugal blower of claim 2, wherein the supporting portion is planar, the ribs extending slantwise upwardly from a periphery of the supporting portion towards the base plate.

4. The centrifugal blower of claim 1, wherein an indent is formed at a center of a top surface of the base plate and a protrusion is formed at a center of the bottom surface of the base plate, corresponding to the supporting portion.

5. The centrifugal blower of claim 4, wherein a top surface of the supporting portion is substantially coplanar with the bottom surface of the base plate and a bottom surface of the supporting portion is lower than the bottom surface of the base plate.

6. An electronic device comprising:
an enclosure comprising a top cover and a bottom cover; and
a centrifugal blower arranged between the top cover and the bottom cover of the enclosure, comprising:
a base plate defining an air inlet therein, a supporting portion disposed in the air inlet, the supporting portion protruding outwardly beyond an outer surface of the base plate;
a sidewall extending from a periphery of the base plate, the sidewall defining an air outlet therein;
a stator mounted on the supporting portion; and
a rotor rotatably disposed around the stator.

7. The electronic device of claim 6, wherein a plurality of ribs extend from a periphery of the supporting portion to connect with the base plate, the air inlet being divided into a plurality of sector-shaped apertures by the ribs.

8. The electronic device of claim 7, wherein the supporting portion is planar, the ribs extending slantwise upwardly from a periphery of the supporting portion towards the base plate.

9. The electronic device of claim 6, wherein an indent is formed at a center of an inner surface of the base plate and a protrusion is formed at a center of the outer surface of the base plate, corresponding to the supporting portion.

10. The electronic device of claim 9, wherein an inner surface of the supporting portion is substantially coplanar with the outer surface of the base plate and an outer surface of the supporting portion is lower than the outer surface of the base plate.

11. The electronic device of claim 7, wherein a free end of the side wall of the centrifugal blower abuts one of the top and bottom covers of the enclosure.

12. The electronic device of claim 11, wherein the supporting portion abuts against the other of the top and bottom covers of the enclosure.

13. The electronic device of claim 12, wherein the supporting portion abuts against the top cover, and the free end of the side wall abuts against the bottom cover of the enclosure.

14. The electronic device of claim 12, wherein the supporting portion abuts against the bottom cover, and the free end of the side wall abuts against the top cover of the enclosure.

15. The electronic device of claim 7, wherein the top cover and the bottom cover define a plurality of first through holes and a plurality of second through holes at regions corresponding to the rotor of the centrifugal blower.
